(19) United States
(12) Patent Application Publication
(10) Pub. No.: US 2001/0041444 A1
(43) Pub. Date: Nov. 15, 2001

(54) TIN CONTACT BARC FOR TUNGSTEN POLISHED CONTACTS

(76) Inventors: JEFFREY A. SHIELDS, SUNNYVALE, CA (US); RAMKUMAR SUBRAMANIAN, SAN JOSE, CA (US); BHARATH RANGARAJAN, SANTA CLARA, CA (US)

Correspondence Address: AMIN & TUROCY, LLP, 1900 EAST 9TH STREET, NATIONAL CITY CENTER, 24TH FLOOR,, CLEVELAND, OH, 44114, US

(21) Appl. No.: 09/430,684

(22) Filed: Oct. 29, 1999

(51) Int. Cl. H01L 21/302; H01L 21/461

(52) U.S. Cl. 438/689

(57) ABSTRACT

The present invention provides improved critical dimension control on oxide films using a titanium nitride (TiN) antireflection coating (ARC). The present invention also provides for improved methods for forming more uniform local interconnects and contact holes through oxide films, by providing a TiN layer as an ARC layer. The TiN ARC layer is used in a process for etching contacts and filling the contacts with a barrier metal made out of Ti or TiN and a tungsten fill. The TiN layer is easily removed during a tungsten polish, which also removes the barrier metal. Additionally, the TiN can serve as a hardmask for the contact etch, since the chemistry is typically selective to TiN. This allows the resist to be thinned down, providing the lithography process with a larger process window.

### TECHNICAL FIELD

The present invention generally relates to semiconductor processing, and in particular to a method for improving a contact lithography process.

### BACKGROUND OF THE INVENTION

In the semiconductor industry, there is a continuing trend toward higher device densities. To achieve these high densities there has been and continues to be efforts toward scaling down device dimensions at submicron levels on semiconductor wafers. In order to accomplish such high device packing density, smaller and smaller feature sizes are required. This may include the width and spacing of interconnecting lines and the surface geometry such as corners and edges of various features.

The requirement of small features with close spacing between adjacent features requires high resolution photolithographic processes. In general, lithography refers to processes for pattern transfer between various media. It is a technique used for integrated circuit fabrication in which a silicon slice, the wafer, is coated uniformly with a radiation-sensitive film, the resist, and an exposing source (such as optical light, x-rays, or an electron beam) illuminates selected areas of the surface through an intervening master template, the mask, for a particular pattern. The lithographic coating is generally a radiation-sensitive coating suitable for receiving a projected image of the subject pattern. Once the image is projected, it is indelibly formed in the coating. The projected image may be either a negative or a positive of the subject pattern. Exposure of the coating through a photomask causes the image area to become either more or less soluble (depending on the coating) in a particular solvent developer. The more soluble areas are removed in the developing process to leave the pattern image in the coating as less soluble polymer.

Present techniques in optical projection printing can resolve images of submicron when photoresists with good linewidth control are used. However, reflection of light from substrate/resist interfaces produce variations in light intensity and scattering of light in the resist during exposure, resulting in non-uniform photoresist linewidth upon development.

Constructive and destructive interference resulting from reflected light is particularly significant when monochromatic or quasi-monochromatic light is used for photoresist exposure. In such cases, the reflected light interferes with the incident light to form standing waves within the resist. In the case of highly reflective substrate regions, the problem is exacerbated since large amplitude standing waves create thin layers of underexposed resist at the wave minima. The underexposed layers can prevent complete resist development causing edge acuity problems in the resist profile.

Antireflective coatings are known and used to mitigate the aforementioned problems, however, the use thereof presents additional problems such as, for example, introduction of particulate contamination, requirement of tight temperature tolerances during production, etc.

A conventional method for employing an antireflective coating is illustrated in FIGS. 1a-1e in connection with a semiconductor structure 18. FIG. 1a illustrates an insulation layer 20 formed on a silicon layer 16. An antireflective layer 22 is formed on the insulation layer 20. It is to be appreciated that the antireflective layer 22 may or may not be employed. If employed, the layer 22 will need to be subsequently removed. Typically, the antireflective layer 22 is a thin silicon oxynitride (SiON) or a silicon nitride (SiN) layer. A photoresist layer 24 is formed on the antireflective layer 22. As shown, the photoresist layer 24 is substantially thick (e.g., 5,000-10,000 Å).

The photoresist layer 24 is patterned using conventional techniques to form a first opening 30 (FIG. 1b). Anisotropic reactive ion etching (RIE) is performed to form a via 40 (FIG. 1c) in the antireflective layer 22 and the insulation layer 20. After via 40 is etched, the photoresist layer 24 is stripped and the via is filled with a barrier metal 26 (typically titanium (Ti) and/or titanium nitride (TiN)) and then with tungsten 28 (FIG. 1d). The tungsten 28 and the barrier metal 26 is then polished away (FIG. 1e) using a tungsten polish (not shown). However, the tungsten polish does not polish silicon oxidynitride or silicon nitride very well and the antireflective layer 22 remains. The thickness of the SiON or SiN layer varies somewhat due to the polish and makes the antireflective layer difficult to inspect for defects due to large color variations in the SiON or SiN film. Removal after the polish becomes difficult because the removal of the SiON or SiN will most likely thin the insulation layer 20.

In view of the above, improvements are needed to improve the removal process of the antireflective layer after the via is formed, filled and polished.

### SUMMARY OF THE INVENTION

The present invention improves critical dimension control on oxide films by using a titanium nitride (TiN) antireflection coating (ARC). The present invention also provides for improved methods for forming more uniform local interconnects and contact holes through oxide films, by providing a TiN layer as an ARC layer. The TiN ARC layer is used in a process for etching contacts and filling the contacts with a barrier metal made out of Ti or TiN and a tungsten fill. The TiN layer is easily removed during a tungsten polish, which also removes the barrier metal. Additionally, the TiN can serve as a hardmask for the contact etch, since the chemistry is typically selective to TiN. This affords fro use of a substantially thin resist which provides the lithography process with a larger process window. Moreover, if desired the TiN does not have to be removed since a conductive metal layer will likely be formed subsequently thereon as another conductive layer. As noted above, the convention SiON layer if employed will need to be removed—and removal thereof may be difficult and/or lead to deleterious effects.

One aspect of the invention relates to a method for fabricating interconnecting lines and vias in a layer of insulating material. The method includes the steps of providing a substrate having an insulating layer, forming a titanium nitride antireflective layer over the insulating layer, providing a photoresist over the antireflective layer, developing the photoresist exposing portions of the antireflective layer, removing the exposed portions of the antireflective layer exposing portions of the insulating layer and removing the exposed portions of the insulating layer to form a via.

Another aspect of the present invention relates to a method for fabricating interconnecting lines and vias in a layer of insulating material. The method includes the steps of providing a substrate having an insulating layer, forming a titanium nitride antireflective layer over the insulating, providing a photoresist over the antireflective layer developing the photoresist exposing portions of the antireflective layer, removing the exposed portions of the antireflective layer exposing portions of the insulating layer, etching exposed portions of the insulating layer to form a via, stripping off the photoresist layer, filling the via with a barrier material layer, the barrier material covering the antireflective layer, filling the via with tungsten material layer, the tungsten material layer covering the barrier material and polishing back the tungsten material layer, the barrier material layer and the antireflective layer using a tungsten polish.

Yet another aspect of the present invention provides for a method for fabricating interconnecting lines and vias in a layer of insulating material comprising the steps of:

providing a substrate having an insulating layer; forming a titanium nitride antireflective layer over the insulating layer; providing a thin photoresist layer over the titanium nitride antireflective layer; developing the thin photoresist layer exposing portions of the antireflective layer; etching the exposed portions of the titanium nitride antireflective layer exposing portions of the insulating layer using a MERIE method with reactant gases of CL₂ (30-200 sccm) and BCL₃ (10-200 sccm) at a power level within the range of about 300-800 W, and pressure within the range of about 60-400 mT; etching exposed portions of the insulating layer to form a via; stripping off the photoresist layer; filling the via with a barrier material layer, the barrier material covering the antireflective layer; filling the via with tungsten material layer, the tungsten material layer covering the barrier material layer; polishing back the tungsten material layer and the barrier material layer; and forming a second metal layer over the antireflective layer.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1a is a schematic illustration of a semiconductor substrate covered with an oxide layer, a silicon oxynitride layer and a photoresist layer in accordance with a conventional process;

FIG. 1b is a schematic illustration of the photoresist layer of FIG. 1a patterned in accordance with a conventional process;

FIG. 1c is a schematic illustration of the structure of FIG. 1b after the silicon oxynitride layer and the oxide layer has been etched in accordance with a conventional process;

FIG. 1d is a schematic illustration of the structure of FIG. 1c after a titanium or titanium nitride barrier and a tungsten fill have been deposited in accordance with a conventional process;

FIG. 1e is a schematic illustration of the structure of FIG. 1d after the titanium or titanium nitride barrier and the tungsten fill have been polished back in accordance with a conventional process;

FIG. 2 is a schematic illustration of a semiconductor substrate covered with an oxide layer, a titanium nitride layer and a photoresist layer in accordance with the present invention;

FIG. 3 is a schematic illustration of the structure of FIG. 2 after the photoresist layer has been patterned in accordance with the present invention;

FIG. 4 is a schematic illustration of the structure of FIG. 3 undergoing an etching step in accordance with the present invention;

FIG. 5 is a schematic illustration of the structure of FIG. 4 after the etching step is substantially complete in accordance with the present invention;

FIG. 6 is a schematic illustration of the structure of FIG. 5 undergoing a second etching step in accordance with the present invention;

FIG. 7 is a schematic illustration of the structure of FIG. 6 after the second etching step is substantially complete in accordance with the present invention;

FIG. 8 is a schematic illustration of the structure of FIG. 7 undergoing a stripping step to remove excess photoresist in accordance with the present invention;

FIG. 9 is a schematic illustration of the structure of FIG. 8 after the stripping step is substantially complete in accordance with the present invention;

FIG. 10 is a schematic illustration of the structure of FIG. 9 undergoing a contact fill step in accordance with the present invention;

FIG. 11 is a schematic illustration of the structure of FIG. 10 after the contact fill step is substantially complete in accordance with the present invention;

FIG. 12 is a schematic illustration of the structure of FIG. 11 undergoing a polishing step in accordance with the present invention; and

FIG. 13 is a schematic illustration of the structure of FIG. 12 after the polishing step is substantially complete in accordance with the present invention.

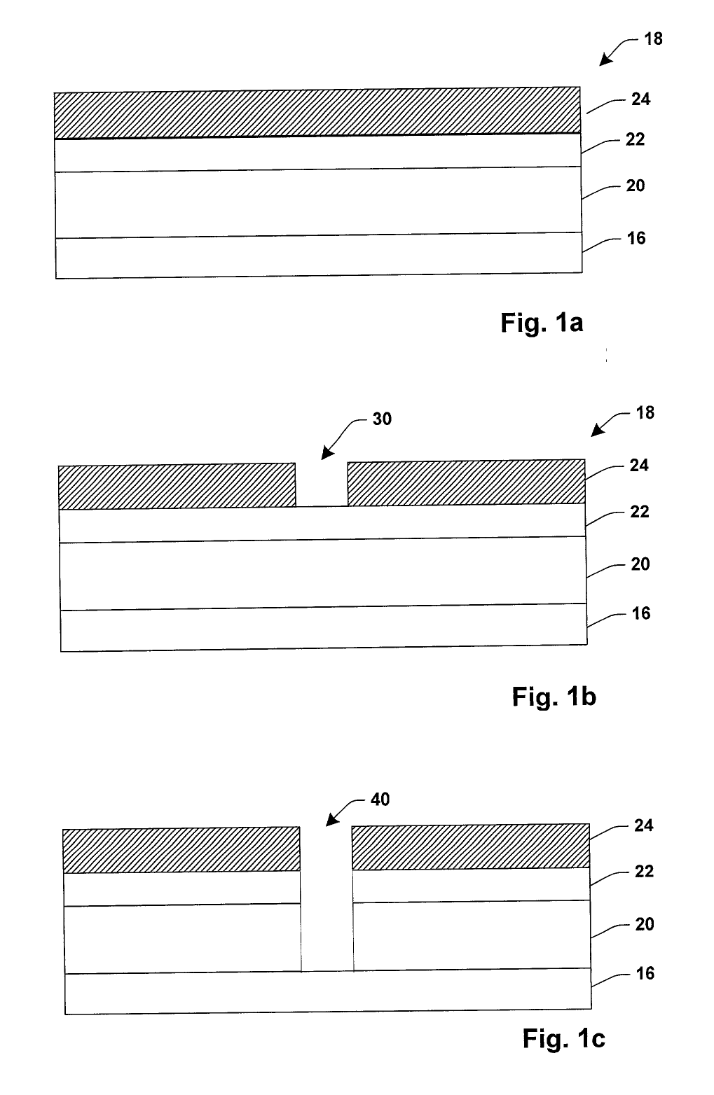

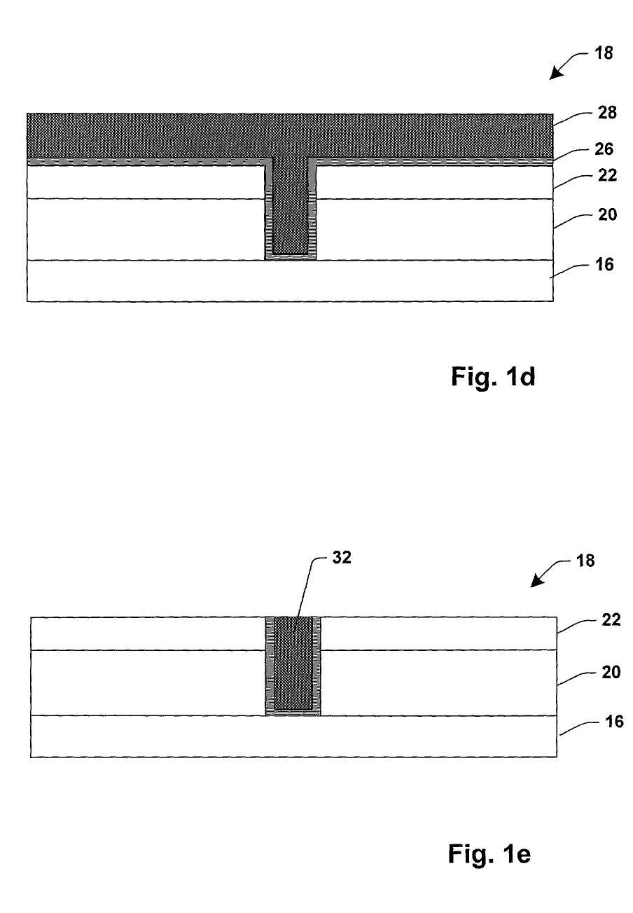

### DETAILED DESCRIPTION OF THE INVENTION

The present invention will now be described with reference to the drawings, wherein like reference numerals are used to refer to like elements throughout.

The present invention involves making and using a titanium nitride or titanium ARC. The present invention more specifically involves making and using a titanium nitride ARC over an oxide underlying layer. The properties of the underlying oxide layer (relative to the titanium nitride ARC, a layer over which a titanium nitride ARC is formed) that the titanium nitride ARC addresses include high optical transparency, significant variations in reflectivities of the layers and features under the underlying oxide layer, and significant variation in thickness of the oxide layer. Thus, the present invention provides for mitigating effects of high optical transparency of oxide layers, methods of minimizing the effects of significant variations in reflectivities of layers and features under the underlying oxide layer, and mitigating the effects of significant variations in thickness of the oxide layer.

The ARCs of the present invention are used over oxide layers to mitigate deleterious affects on the photoresist patterning process. The underlying oxide layer may be any oxide film or coating, but typically is an oxide dielectric layer. Specific examples of underlying oxide layers include metal oxides, silicon dioxide, phosphosilicate glass (PSG), tetraethylorthosilicate (TEOS), borphosphosilicate glass (BPSG), or any other suitable glass.

The layers and features under the underlying oxide layer include any material or device used in semiconductor structures and thus have diverse reflectivies. For example, typically metal layers have reflectivies of about 80% or more, polysilicons have reflectivities of abut 50% and metal nitrides have reflectivities of about 30%. In one embodiment, the layers and/or features under the underlying oxide layer have at least two different reflectivities that vary by more than about 20% at the exposure wavelength.

The titanium nitride ARC of the present invention may be made by initially forming a titanium nitride layer on an underlying oxide layer. The Titanium nitride layer may be formed using any suitable technique including chemical vapor deposition (CVD) techniques, such as low pressure chemical vapor deposition (LPCVD) or =plasma enhanced chemical vapor deposition (PECVD). The titanium nitride ARC is formed to a suitable thickness to exhibit a desired antireflectivity. The reflectivity of the resultant titanium nitride ARC varies with the thickness. In one embodiment, the titanium nitride ARC formed in accordance with the present invention has a thickness from about 100-1200 Å. In another embodiment, the titanium nitride ARC formed in accordance with the present invention has a thickness from about 200-600 Å. In yet another embodiment, the titanium nitride ARC formed in accordance with the present invention has a thickness from about 250-500 Å.

The titanium nitride ARC as formed in accordance with the present invention has some absorption characteristics at the exposure wavelengths, such as below about 450 nm, and even below about 300 nm. For example, the titanium nitride ARC of the present invention has some absorption characteristics at wavelengths of about 436 nm, about 405 nm, abut 365 nm, about 308 nm, about 248 nm, about 193 nm about 193 nm, about 157 nm, 13 nm and 11 nm. In one embodiment, the titanium nitride ARC has a reflectivity of less than about 40% on a 1 micron thick oxide film over silicon at at least one of the wavelengths listed above. In another embodiment, the titanium nitride ARC has a reflectivity of less than about 35% on a 1 micron thick oxide film over silicon at at least one of the wavelengths listed above. In yet another embodiment, the titanium nitride ARC has a reflectivity of less than about 30% on a 1 micron thick oxide film over silicon at at least one of the wavelengths listed above.

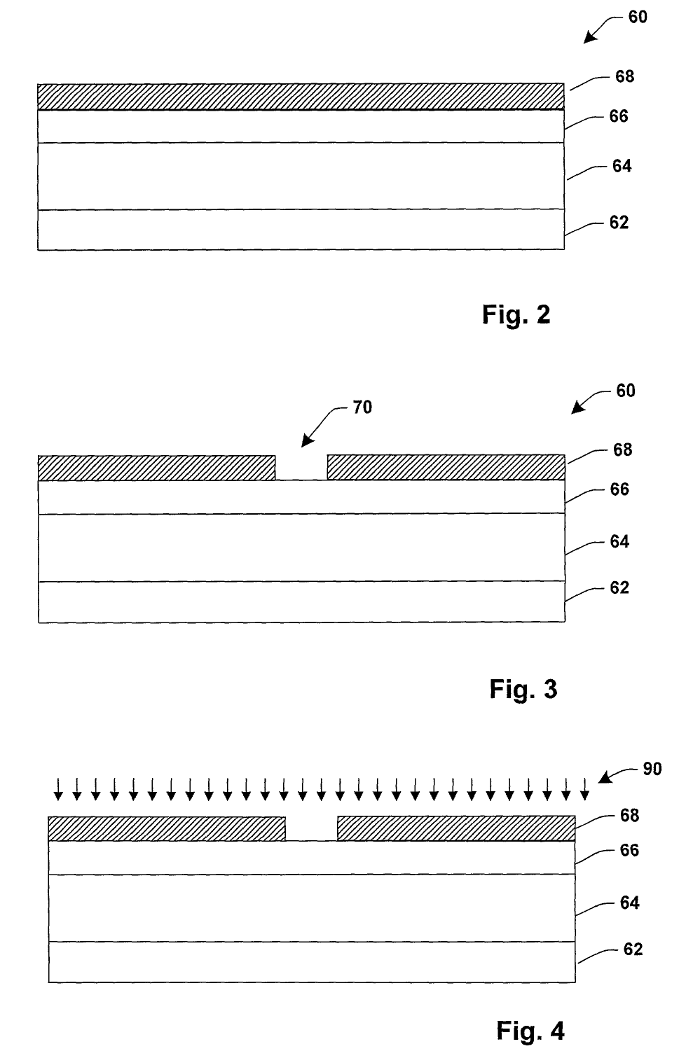

FIGS. 2-13 illustrate an embodiment of the present invention. With regard to the description in connection with the embodiment of FIGS. 2-13, the term substrate includes not only a semiconductor substrate, but also any and all layers and structures fabricated over the semiconductor substrate up to the point of processing under discussion.

FIG. 2 illustrates a semiconductor device 60 including an insulating layer 64 which is formed on a semiconductor substrate 62. Semiconductor substrate 62 may be any suitable semiconductor material, for example, a monocrystalline silicon substrate. Any suitable technique (e.g., thermal oxidation, plasma enhanced chemical vapor deposition (CVD), thermal enhanced CVD and spin on techniques) may be employed in forming the insulating layer 64. Preferably, the insulating layer 64 is silicon dioxide (SiO₂) with a thickness of about 0.8 to 1.0 microns. Other usuable insulating materials are silicon nitride (Si₃N₄), (SiN), silicon oxynitride (SiOₓN_{y}), and fluonated silicon oxide (SiOₓF_{y}), and polyimide(s).

An ARC layer 66 made of titanium nitride or titanium is formed over the insulating layer 64 using CVD techniques. Any suitable technique for forming the titanium nitride layer 66 may be employed such as Low Pressure Chemical Vapor Deposition (LPCVD), Plasma Enhanced Chemical Vapor Deposition (PECVD), High Density Chemical Plasma Vapor Deposition (HDPCVD), sputtering or high density plasma chemical vapor deposition (HDPCVD) techniques to a thickness suitable for serving as a hard mask for a selective etch of the insulating layer 64. Thus, for example, in one aspect of the present invention the thickness of the titanium nitride layer 66 is between the range of about 50 Å-5000 Å. In another aspect, the thickness of the titanium nitride layer 66 is between the range of about 50 Å-3000 Å. In another aspect, the thickness of the titanium nitride layer 66 is between the range of about 50 Å-2000 Å. In another aspect, the thickness of the titanium nitride layer 66 is between the range of about 50 Å-1500 Å. In another aspect, the thickness of the titanium nitride layer 66 is between the range of about 50 Å-1000 Å. In still another aspect, the thickness of the titanium nitride layer 66 is between the range of about 50 Å-500 Å.

A thin photoresist layer 68 is formed on the titanium nitride layer 66. The thin photoresist layer 68 has a thickness of about 500 Å-5000 Å, however, it is to be appreciated that the thickness thereof may be of any dimension suitable for carrying out the present invention. Accordingly, the thickness of the thin photoresist layer 68 can vary in correspondence with the wavelength of radiation used to pattern the thin photoresist layer 68. One aspect of the present invention provides for forming the thin photoresist layer 68 to have a thickness within the range of 1000 Å to 4000 Å. Another aspect of the present invention provides for forming the thin photoresist layer 68 to have a thickness within the range of 2000 Å to 3000 Å. Yet another aspect of the present invention provides for forming the thin photoresist layer 68 to have a thickness within the range of 500 Å to 2000 Å. The thin photoresist layer 68 may be formed over the titanium nitride layer 66 via conventional spin-coating or spin casting deposition techniques.

The thin photoresist layer 68 has a thickness suitable for functioning as a mask for etching the underlying titanium nitride layer 66 and for forming patterns or openings in the developed thin photoresist layer 68. Since the thin photoresist layer 68 is relatively thin compared with I-line, regular deep UV and other photoresists, improved critical dimension control is realized.

The photoresist layer 68 is patterned using conventional techniques to form a first opening 70 (FIG. 3). The size of the first opening 70 is about the size of the ultimate via. The patterned photoresist 68 serves as an etch mask layer for processing or etching the underlying titanium nitride layer 66.

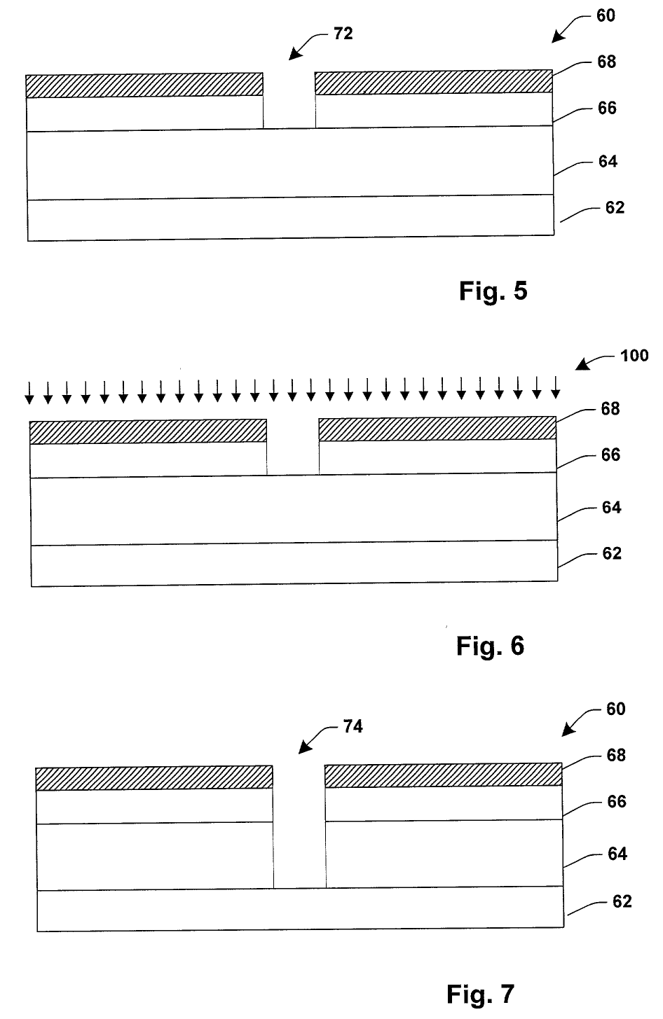

An etch step 90 (e.g., anisotropic reactive ion etching (RIE)) (FIG. 4) is performed to form a via 72 (FIG. 5) in the titanium nitride layer 66. The patterned photoresist 68 is used as a mask for selectively etching the titanium nitride layer 66 to provide patterned titanium nitride layer 66. Any suitable etch technique may be used to etch the titanium nitride layer 66. Preferably, a selective etch technique may be used to etch the material of the titanium nitride layer 66 at a relatively greater rate as compared to the rate that the material of the patterned photoresist 68 is etched. The etch step 90 is also highly selective to the titanium nitride layer 66 over the underlying insulating layer 64, so as to mitigate damage to the insulating layer 64. The titanium nitride layer 66 comprises a metal such as Ti or TiN, the titanium nitride layer 66 may be etched with Cl₂ chemistry using magnetic enhanced reactive ion etching (MERIE), electron cyclotron etching (ECR), or conventional reactive ion etching (RIE) methods. According to the present example, a MERIE method is used with reactant gases of C1₂ (30-200 sccm) and BCL₃ (10-200 sccm) at a power level within the range of about 300-800 W, and pressure within the range of about 60-400 mT. This chemistry has reasonably high selectivity to metal material over insulating material, and the selectivity of various embodiments, respectively, may be tailored to be greater than 5:1; greater than 6:1; greater than 7:1; greater than 8:1; greater than 9:1; and greater than 10:1 depending on the particular embodiment employed. The etch step 90 is also highly selective to the titanium nitride layer 66 over the underlying insulating layer 64 so as to mitigate damage to the insulating layer 64. This chemistry has reasonably high selectivity to metal material over photoresist material, and the selectivity of various embodiments, respectively, may be tailored to be greater than 5:1; greater than 10:1; greater than 20:1; greater than 30:1; and greater than 40:1 depending on the particular embodiment employed.

Turning now to FIG. 6, the insulating layer 64 is shown undergoing an etching process 100 wherein the patterned titanium nitride layer 66 serves as a hard mask. For example, the etching process 100 may include a reactive ion etch (RIE), that is highly selective to the insulating layer 64 with respect to the patterned titanium nitride layer 66. It is to be appreciated that any suitable etch methodology for selectively etching the insulating layer 64 over the patterned titanium nitride layer 66 may be employed and is intended to fall within the scope of the hereto appended claims. For example, the insulating layer 64 at the first opening 72 is anisotripically etched with a plasma gas(es), herein carbon tetrafloride (CF₄) containing fluorine ions, in a commercially available etcher, such as a parallel plate RIE apparatus or, alternatively, an electron cyclotron resonance (ECR) plasma reactor to replicate the mask pattern of the patterned photoresist layer 68 to thereby create the via 74 in the insulating layer 64 (FIG. 7).

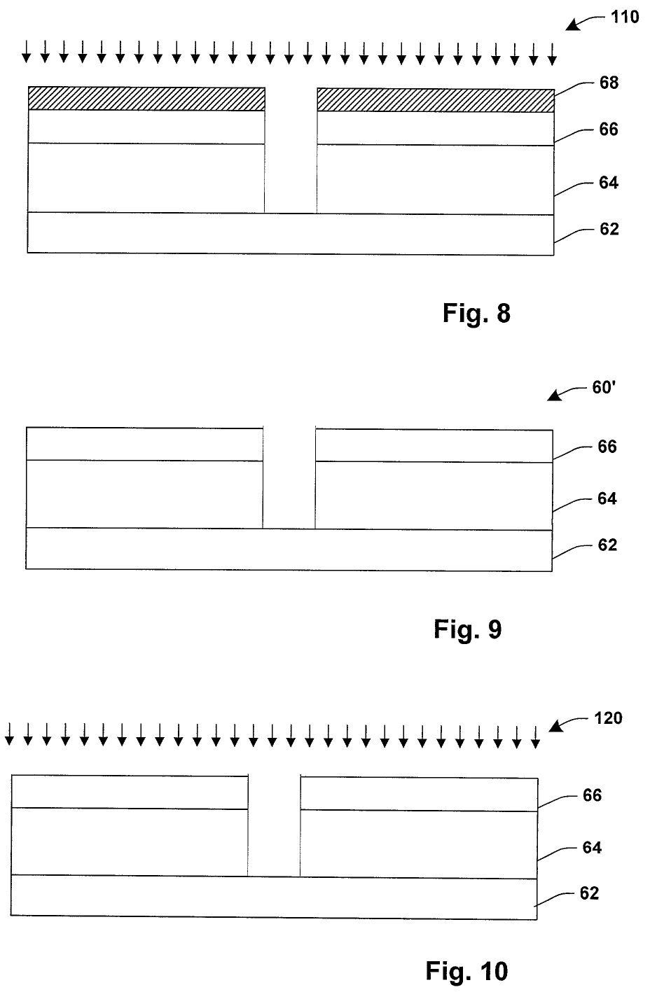

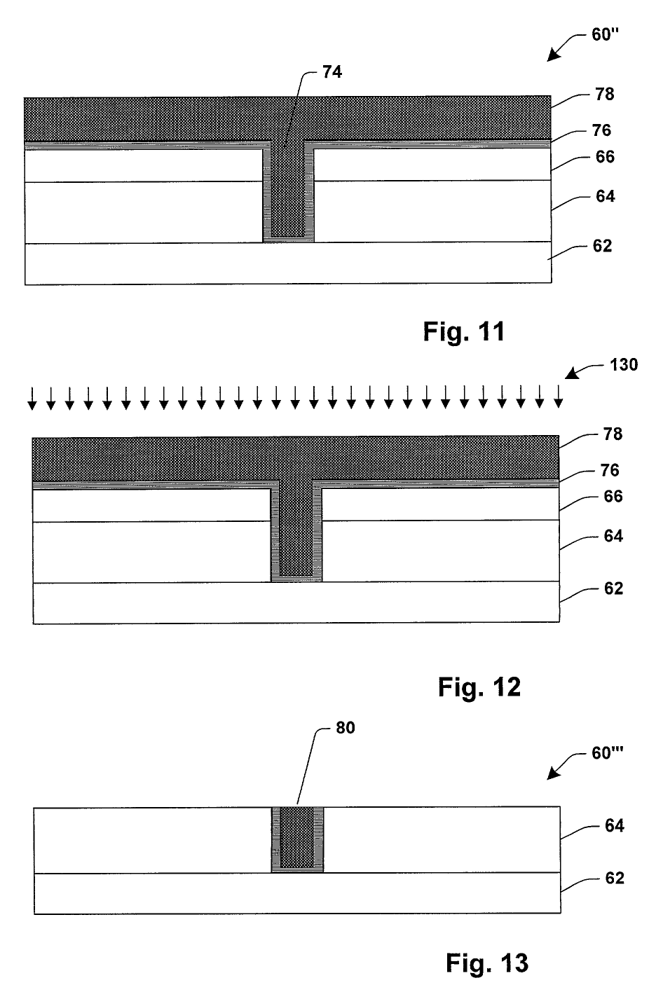

FIG. 8 illustrates a stripping step 110 (e.g., ashing in an 02 plasma) to remove remaining portions of the photoresist layer 68. FIG. 9 illustrates a partially complete semiconductor structure 60′ after the stripping step 100 is substantially complete. Next, a deposition step 120 is performed on the structure 60′ (FIG. 10) to form a protective barrier layer 76 over the structure 60′. Preferably, the protective barrier layer 76 is comprised of Ti or TiN. The deposition step 120 also includes depositing a tungsten layer 78. FIG. 11 illustrates a partially complete semiconductor device 60″.

FIG. 12 illustrates a polished back step 130 being performed to remove a predetermined thickness of the protective barrier layer 76 and the tungsten layer 78. The polish back step includes using a tungsten polish that is selective to removing Ti and TiN, so that the titanium nitride layer 66 made of Ti and/or TiN is easily removed in the process as compared to SiON ARC layer in conventional processes. Preferably, the polished back step 140 is performed to remove an amount of the protective barrier layer 76, the tungsten layer 78 and the titanium nitride layer 66 equivalent to the thickness of the protective barrier layer 76, the tungsten layer 78 and the titanium nitride layer 66. Moreover, if desired the TiN layer does not have to be removed since a conductive metal layer will likely be formed subsequently thereon as another conductive layer. As noted above, the convention SiON layer if employed will need to be removed—and removal thereof may be difficult and/or lead to deleterious effects.

Substantial completion of the polished back step 130 results in a structure 60′″ shown in FIG. 13. The structure 60′″ includes the semiconductor substrate 62, the insulating layer 64 and a contact 80 connecting the semiconductor substrate 62 to a top surface of the insulating layer.

What has been described above are preferred embodiments of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A method for fabricating interconnecting lines and vias in a layer of insulating material comprising the steps of:
providing a substrate having an insulating layer;
forming a titanium nitride antireflective layer over the insulating layer;
providing a thin photoresist layer over the antireflective layer;
developing the photoresist layer exposing portions of the titanium nitride antireflective layer;
removing the exposed portions of the titanium nitride antireflective layer exposing portions of the insulating layer; and
removing exposed portions of the insulating layer to form a via.

2. The method of claim 1, the insulating layer including at least one of silicon oxide, silicon dioxide, silicon nitride (Si₃N₄), (SiN), silicon oxynitride, (SiOₓN_{y}), fluonated silicon oxide (SiOₓF_{y}), and polyimide(s).

3. The method of claim 1, further including the step of filling the via with a metal.

4. The method of claim 3, the metal including at least one of tungsten and a tungsten alloy.

5. The method of claim 1, wherein the first removing step is highly selective to the titanium nitride layer over the photoresist layer.

6. The method of claim 1, wherein the second removing step is highly selective to the insulating layer over the titanium nitride layer.

7. The method of claim 1, further including the step of forming the titanium nitride layer to have a thickness within the range of about 50 Å-2000 Å.

8. The method of claim 1, further including the step of forming the titanium nitride layer to have a thickness within the range of about 50 Å-1500 Å.

9. The method of claim 1, further including the step of forming the titanium nitride layer to have a thickness within the range of about 50 Å-1000 Å.

9. The method of claim 1, further including the step of forming the titanium nitride layer to have a thickness within the range of about 50 Å-500 Å.

10. The method of claim 1, further including the step of forming the thin photoresist layer to have a thickness within the range of about 500 Å to 5000 Å.

11. The method of claim 1, further including the step of forming the thin photoresist layer to have a thickness within the range of about 1000 Å to 4000 Å.

12. The method of claim 1, further including the step of forming the thin photoresist layer to have a thickness within the range of about 500 Å to 2000 Å.

13. The method of claim 1, further including an etch chemistry for the first removal having a selectivity to the titanium nitride layer over the thin photoresist layer greater than about 40:1.

14. The method of claim 1, further including an etch chemistry for the first removal step having a selectivity to the titanium nitride layer over the thin photoresist layer greater than about 30:1.

15. The method of claim 1, further including an etch chemistry for the first removal step having a selectivity to the titanium nitride layer over the thin photoresist layer greater than about 20:1.

16. The method of claim 1, further including an etch chemistry for the first removal step having a selectivity to the titanium nitride layer over the thin photoresist layer greater than about 10:1.

17. The method of claim 1, further including an etch chemistry for the first removal step having a selectivity to the titanium nitride layer over the thin photoresist layer greater than about 5:1.

18. The method of claim 1, further including an etch chemistry for the second removal step having a selectivity to the insulating layer over the titanium nitride layer greater than about 5:1.

19. The method of claim 1, further including an etch chemistry for the second removal step having a selectivity to the insulating layer over the titanium nitride layer greater than about 10:1.

20. The method of claim 1, wherein the first removal step includes using a MERIE method with reactant gases of CL₂ (30-200 sccm) and BCL₃ (10-200 sccm) at a power level within the range of about 300-800 W, and pressure within the range of about 60-400 mT.

21. A method for fabricating interconnecting lines and vias in a layer of insulating material comprising the steps of:
providing a substrate having an insulating layer;
forming a titanium nitride antireflective layer over the insulating layer;
providing a thin photoresist layer over the titanium nitride antireflective layer;
developing the thin photoresist layer exposing portions of the antireflective layer;
etching the exposed portions of the titanium nitride antireflective layer exposing portions of the insulating layer;
etching exposed portions of the insulating layer to form a via;
stripping off the photoresist layer;
filling the via with a barrier material layer, the barrier material covering the antireflective layer;
filling the via with tungsten material layer, the tungsten material layer covering the barrier material layer; and
polishing back the tungsten material layer, the barrier material layer and the antireflective layer using a tungsten polish.

22. The method of claim 21, wherein the first etching step is highly selective to the titanium nitride layer over the thin photoresist layer.

23. The method of claim 21, wherein the second etching step is highly selective to the insulating layer over the titanium nitride layer.

24. The method of claim 21, further including the step of forming the titanium nitride layer to have a thickness within the range of about 50 Å-2000 Å.

25. The method of claim 21, further including the step of forming the thin photoresist layer to have a thickness within the range of about 500 Å to 2000 Å.

26. The method of claim 21, further including an etch chemistry for the first etch having a selectivity to the titanium nitride layer over the thin photoresist layer greater than about 40:1.

27. The method of claim 12, further including an etch chemistry for the second removal step having a selectivity to the insulating layer over the titanium nitride layer greater than about 10:1.

28. The method of claim 21, wherein the first etch step includes using a MERIE method with reactant gases of CL₂ (30-200 sccm) and BCL₃ (10-200 sccm) at a power level within the range of about 300-800 W, and pressure within the range of about 60-400 mT.

29. A method for fabricating interconnecting lines and vias in a layer of insulating material comprising the steps of:
providing a substrate having an insulating layer;
forming a titanium nitride antireflective layer over the insulating layer;
providing a thin photoresist layer over the titanium nitride antireflective layer;
developing the thin photoresist layer exposing portions of the antireflective layer;
etching the exposed portions of the titanium nitride antireflective layer exposing portions of the insulating layer using a MERIE method with reactant gases of CL₂ (30-200 sccm) and BCL₃ (10-200 sccm) at a power level within the range of about 300-800 W, and pressure within the range of about 60-400 mT;
etching exposed portions of the insulating layer to form a via;
stripping off the photoresist layer;
filling the via with a barrier material layer, the barrier material covering the antireflective layer;
filling the via with tungsten material layer, the tungsten material layer covering the barrier material layer;
polishing back the tungsten material layer and the barrier material layer; and
forming a second metal layer over the antireflective layer.
